(19) United States
(12) Patent Application Publication
(10) Pub. No.: US 2003/0112158 A1
(43) Pub. Date: Jun. 19, 2003

(54) Miniature magnetic device package

(76) Inventor: Brian George Babin, Goshen, IN (US)

Correspondence Address: John S. Paniaguas, KATTEN MUCHIN ZAVIS ROSENMAN, Suite 1600, 525 West Monroe Street, Chicago, IL, 60661, US

(21) Appl. No.: 10/287,429

(22) Filed: Nov. 4, 2002

Related U.S. Application Data
(60) Provisional application No. 60/332,649, filed on Nov. 5, 2001.
(60) Provisional application No. 60/332,590, filed on Nov. 5, 2001.
(60) Provisional application No. 60/333,260, filed on Nov. 5, 2001.

(51) Int. Cl. H03M 1/22

(52) U.S. Cl. 341/15

(57) ABSTRACT

A miniature magnetic device package for use in applications as small as 5 mm as disclosed. Three embodiments of the invention are provided. In one embodiment, a magnetic encoder includes a magnetic flux responsive element, such as a Hall effect device, sandwiched between a pair of pole pieces, forming a subassembly. A resin, such as epoxy or a thermoplastic material is overmolded over the subassembly forming a housing. The magnetic flux responsive element is configured such that its major axis is generally parallel with a major axis of the housing, thus providing a sensor package with a footprint around 5 mm. The flux concentrators may be configured in an L-shape to provide magnetic focusing adjacent a sensing face of the housing to focus flux toward the magnetic encoder and the Hall effect device. In a second embodiment of the invention, a magnetic sensor is provided. In this embodiment, a magnetic flux responsive element is sandwiched between a magnet and a flux concentrator. The assembly of the magnetic flux responsive element, flux concentrator and magnet is overmolded by a thermoplastic material. In a third embodiment, a magnetic flux responsive element is overmolded with a magnetic resin forming a magnetic sensor.

### CROSS REFERENCE TO RELATED APPLICATIONS

This application is related to and claims the benefit of the following applications: U.S. Patent Application Nos. 60/332,649; 60/332,590; and 60,/333,260; all filed Nov. 5, 2001.

### BACKGROUND OF THE INVENTION

1. Field of the Invention:

The present invention relates to a miniature magnetic device package.

2. Description of the Prior Art:

Various magnetic sensors and magnetic encoders are known in the art for sensing linear and rotary displacement of an object. Magnetic sensors normally include a magnetic flux responsive element, such as a Hall effect device, and a magnet. The magnet is normally mounted at a fixed distance from the Hall effect device. Displacement of a ferrous object or magnet in the vicinity of the sensor changes the amount of flux sensed by the magnetic flux responsive element which provides an indication of the displacement of the object.

Such sensors are used in a wide variety of applications including automotive applications. Many automotive applications are limited by the space available to accommodate such sensors. Certain automotive applications, such as ABS applications, have limited space to accommodate sensors, for example, space as small as approximately 5 mm. As such, magnetic devices, such as sensors or encoders were not heretofore known to be used in such applications. Accordingly, there is a need for miniature magnetic device which can be used in applications requiring sensor footprints as small as around 5 mm.

### SUMMARY OF THE INVENTION

Briefly, the present invention relates to a miniature magnetic device package for use in applications as small as 5 mm. Three embodiments of the invention are provided. In one embodiment, a magnetic encoder includes a magnetic flux responsive element, such as a Hall effect device, sandwiched between a pair of pole pieces, forming a subassembly. A resin, such as epoxy or a thermoplastic material is overmolded over the subassembly forming a housing. The magnetic flux responsive element is configured such that its major axis is generally parallel with a major axis of the housing, thus providing a sensor package with a footprint around 5 mm. The flux concentrators may be configured in an L-shape to provide magnetic focusing adjacent a sensing face of the housing to focus flux toward the magnetic encoder and the Hall effect device. In a second embodiment of the invention, a magnetic sensor is provided. In this embodiment, a magnetic flux responsive element is sandwiched between a magnet and a flux concentrator. The assembly of the magnetic flux responsive element, flux concentrator and magnet is overmolded by a thermoplastic material. In a third embodiment, a magnetic flux responsive element is overmolded with a magnetic resin forming a magnetic sensor.

### DESCRIPTION OF THE DRAWINGS

These and other advantages of the present invention will be readily understood with reference to the following specification and attached drawing wherein:

FIG. 1 is a sectional view in elevation of a miniature magnetic encoder in accordance with the present invention.

FIG. 2 is a sectional view along line 2-2 of FIG. 1.

FIG. 3 is a perspective view of the miniature magnetic encoder illustrated in FIG. 1.

FIG. 4 is a sectional view of a second embodiment of the invention wherein the housing is formed with a magnetic resin forming a miniature magnetic sensor.

FIG. 5 is a perspective view of the miniature magnetic sensor illustrated in FIG. 4.

FIG. 6 is a sectional view of a third alternative embodiment of a miniature magnetic sensor in accordance with the present invention.

FIG. 7 is a sectional view along line 6-6 of FIG. 6.

FIG. 8 is a perspective view of the miniature magnetic sensor illustrated in FIG. 6.

### DETAILED DESCRIPTION

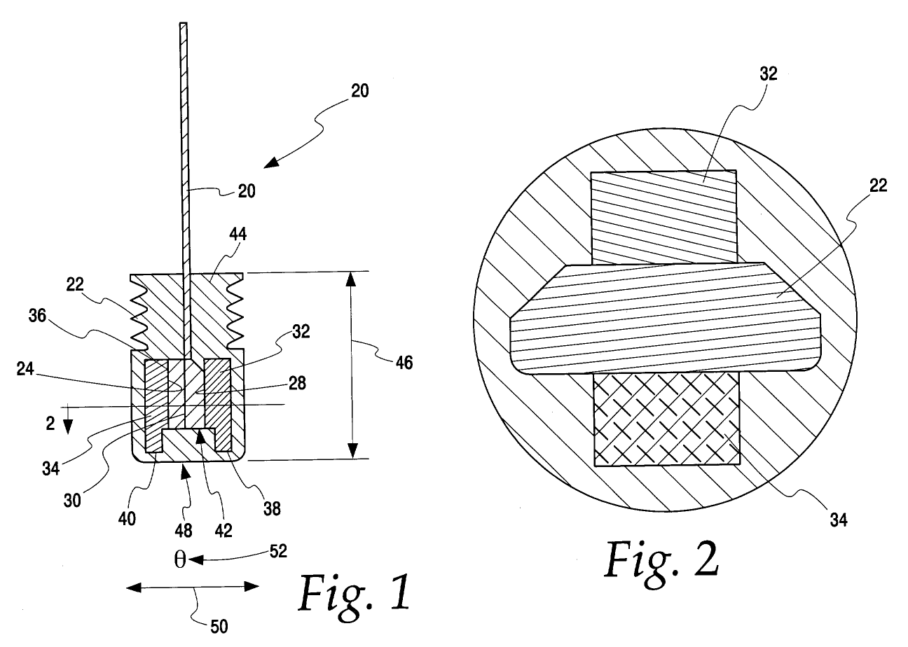

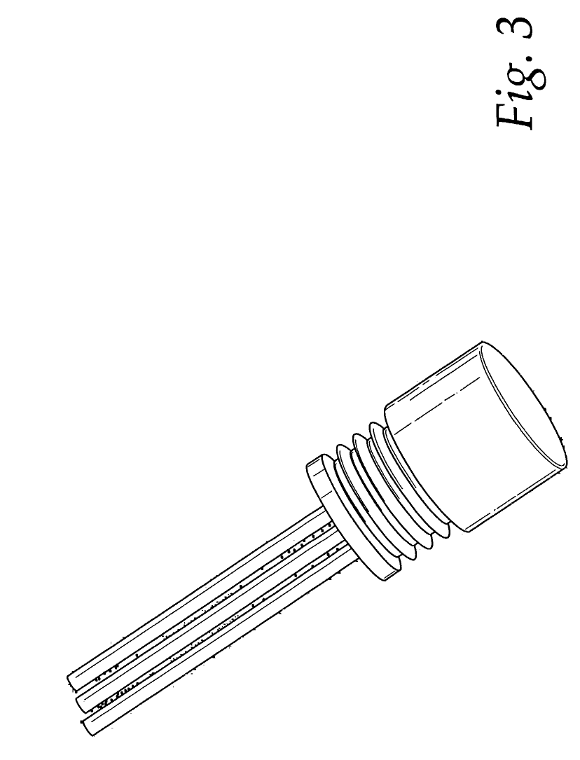

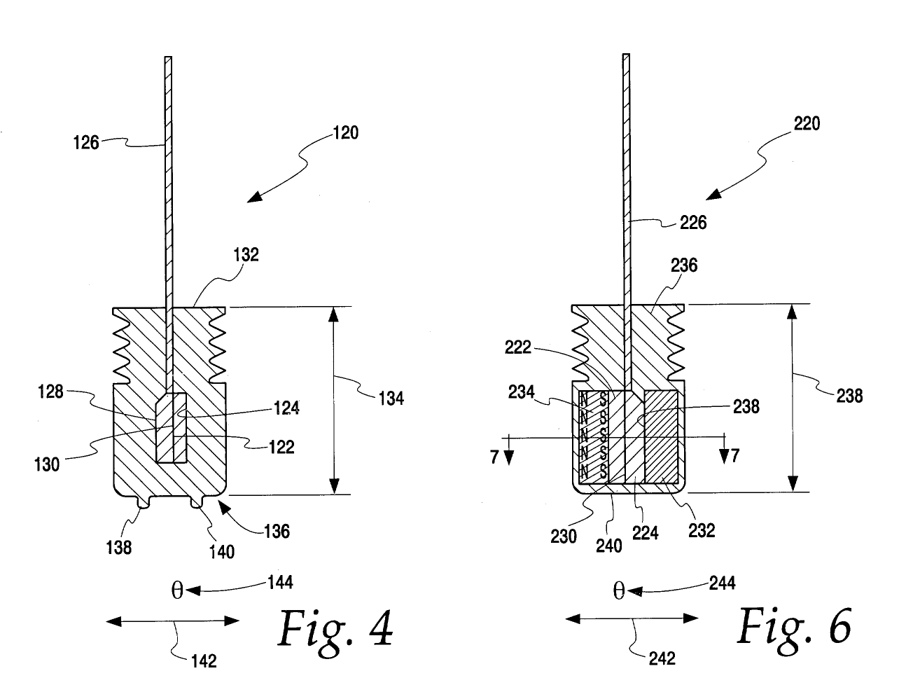

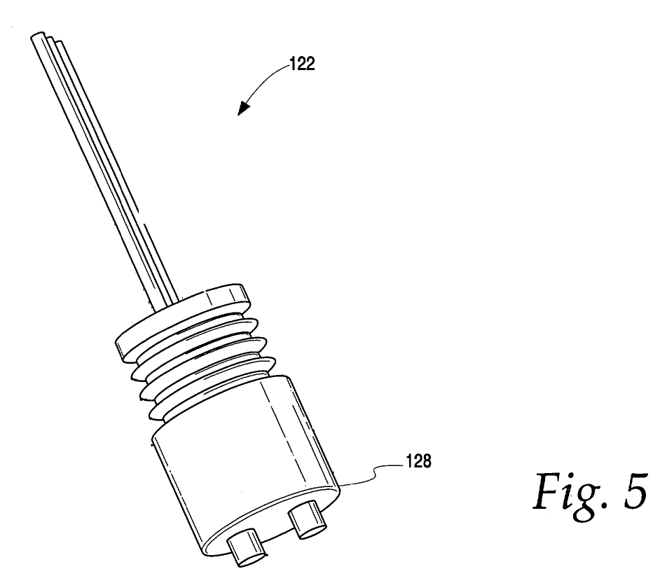

The present invention relates to a miniature magnet device, such as a sensor or encoder, for use in applications where the space limitations limit the footprint of the sensor to around 5 mm, such as ABS bearing applications. Three embodiments of the invention are disclosed. In particular, a first embodiment of the invention is illustrated in FIGS. 1-3. This embodiment relates to a magnetic encoder and includes a magnetic flux responsive element and one or more flux concentrators carried by a housing. The second and third embodiments relate to miniature magnetic sensors. In particular, FIGS. 4 and 5 relate to embodiment where the housing is formed from a magnetic resin while FIGS. 6-8 relate to an embodiment where the sensor includes a separate magnet and the housing is formed from a thermoplastic material.

Referring to FIG. 1, a miniature magnetic encoder, generally identified with the reference numeral 20, as illustrated. The miniature magnetic encoder 20 includes a magnetic flux responsive element 22, which may be a Hall effect device. Such Hall effect devices are integrated circuits which include a generally rectangular housing 24 and a set of 2 or 3 extending leads 26 for connection to an external circuit. Such Hall effect devices are known to include a sensing plane 28 that is generally parallel to a major axis 30 of the rectangular housing 24.

As shown best in FIG. 1, a pair of L-shaped pole pieces or flux concentrators 32 and 34, formed from a ferrous material, are disposed adjacent the sensing plane 28 and an opposing face 36 of the Hall effect device 22, forming a subassembly. As shown, the flux concentrators 32, 34 may be formed in a generally L-shape and configured such that the legs 38 and 40 may extend beyond a bottom surface 42 of the Hall effect device 22. As such, the legs 38 and 40 function to focus magnetic flux between the magnetic encoder and the Hall effect device.

As shown in FIG. 1, a resin, such as an epoxy or thermoplastic material, is molded over the subassembly and may be further molded over a portion of the leads 26 forming a housing 44. In order to further reduce the footprint of the sensor, the Hall effect device 22 is configured such that its major axis 30 is generally parallel with a major axis 46 of the housing 44, as generally shown.

The housing 44 may be formed in a multitude of geometric shapes. A generally circular shape is shown for illustration purposes. A sensing face, generally identified with the reference numeral 48, is formed on one end of the housing 44. The encoder 20 is adapted to sense a magnetic target with, either single or multiple pole pairs, disposed adjacent the sensing face 48. More particularly, with reference to FIG. 1, the encoder 20 is adapted to sense linear motion of a magnetic target in a direction of the arrow 50 or motion of a magnetic target which rotates about an axis 52, that is generally perpendicular to the major axis 30 of the magnetic flux responsive element 22.

As mentioned above, two embodiments of a magnetic sensor are disclosed. One embodiment, illustrated in FIGS. 4 and 5, utilizes a magnetic resin as the housing. The second embodiment, illustrated in FIGS. 6-8, utilizes a magnet and a housing formed from a thermoplastic material.

Referring to FIGS. 4 and 5, the miniature magnetic sensor, generally identified with the reference numeral 120, includes a magnetic flux responsive element 122, which may be a Hall effect device. Such Hall effect devices are integrated circuits which include a generally rectangular housing 124 and a set of 3 extending leads 126 for connection to an external circuit. Such Hall effect devices are known to include a sensing plane 128 that is generally parallel to a major axis 130 of the Hall effect IC rectangular housing 124.

In accordance with an important aspect of this embodiment of the invention, the Hall effect device 122 is overmolded with a magnetic resin, for example, as disclosed in U.S. Pat. No. 6,274,939, hereby incorporated by reference, thereby eliminating the need for a separate magnet in order to reduce the size of the magnetic sensor. As shown in FIG. 4, the magnetic resin 132 is molded over the Hall effect IC housing 124 and may be further molded over a portion of the leads 126. In order to further reduce the footprint of the sensor, the Hall effect device 122 is configured such that its major axis 130 is generally parallel with a major axis 134 of the housing 132 as generally shown.

The housing 132 may be formed in a multitude of geometric shapes in either a isotropic or an anistropic state. A generally circular shape is shown for illustration purposes. A sensing face, generally identified with the reference numeral 136, is formed on one end of the housing 132. The sensing face 136 is adapted to be disposed adjacent a target (not shown), either a ferrous target or another magnet. More particularly, with reference to FIG. 4, the sensor 120 is adapted to sense linear motion of a target in a direction of the arrow 142 or motion of a target which rotates about an axis 144, that is generally perpendicular to the major axis 130 of the magnetic flux responsive element.

The sensing face 136 may be configured with one or more protuberances 138, 140, which act as flux concentrators to focus the flux into the sensor 120. Alternatively, the sensing face 136 may be formed without the flux concentrators.

FIGS. 6-8 relate to a second embodiment of a miniature magnetic sensor. Referring to FIG. 6, the miniature magnetic sensor package, generally identified with the reference numeral 220, includes a magnetic flux responsive element 222, which may be a Hall effect device. Such Hall effect devices are integrated circuits which include a generally rectangular housing 224 and a set of 2 or 3 extending leads 226 for connection to an external circuit. Such Hall effect devices are known to include a sensing plane 228 that is generally parallel to a major axis 230 of the Hall effect IC rectangular housing 224.

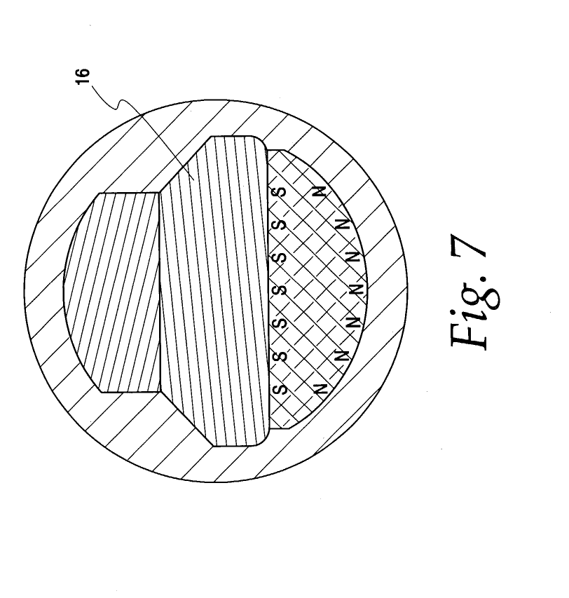

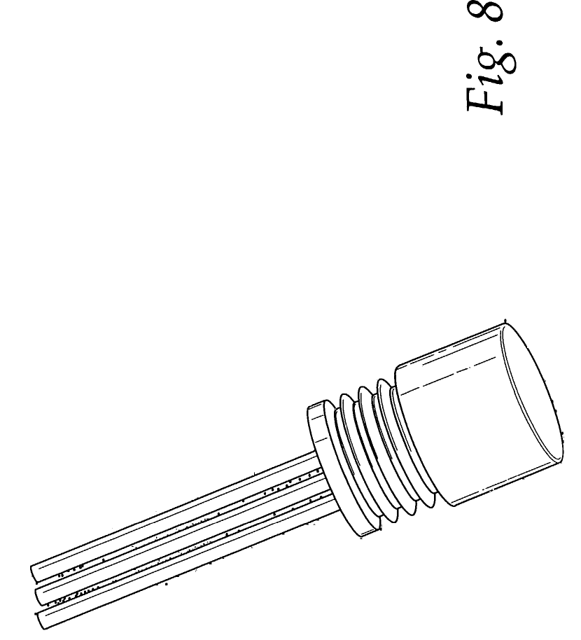

The Hall effect device 222 is sandwiched between a flux concentrator 232, disposed adjacent the sensing plane 228, and a magnet 234 forming a subassembly. The magnet 234 may be configured as shown in FIGS. 7 and 8 or alternatively as disclosed in U.S. Pat. No. 4,970,463.

As shown in FIG. 6, a resin, such as an epoxy or thermoplastic material, is molded over the subassembly and may be molded over a portion of the leads 226 forming a housing 236. In order to further reduce the footprint of the sensor, the Hall effect device is configured such that its major axis 230 is generally parallel with a major axis 238 of the housing, as generally shown.

The housing 236 may be formed in a multitude of geometric shapes. A generally circular shape is shown for illustration purposes. A sensing face, generally identified with the reference numeral 240, is formed on one end of the housing 236. The sensing face 240 is adapted to be disposed adjacent a target (not shown), either a ferrous target or another magnet. More particularly, with reference to FIG. 6, the sensor 220 is adapted to sense linear motion of a target in a direction of the arrow 242 or motion of a target which rotates about an axis 242, that is generally perpendicular to the major axis 30 of the magnetic flux responsive element 222.

Obviously, many modifications and variations of the present invention are possible in light of the above teachings. Thus, it is to be understood that, within the scope of the appended claims, the invention may be practiced otherwise than as specifically described above.

What is claimed and desired to be covered by a Letters Patent is as follows:

We claim:

1. A miniature magnetic device comprising:
a magnetic flux responsive element having two or more extending leads defining a major axis or pair of opposing sides generally parallel to said major axis and a sensing plane formed adjacent to one of said pair or opposing sides; and
a housing molded over said magnetic flux responsive element, said housing configured such that a portion of said extending leads extend outwardly therefrom, said housing configured with a footprint of around 5 mm.

2. The miniature magnetic device recited in claim 1, wherein said device is an encoder and includes one or more flux concentrators.

3. The miniature magnet device as recited in claim 2, wherein said magnetic flux responsive element is a Hall effect device.

4. The miniature magnetic device as recited in claim 2, wherein said housing is configured with a generally circular cross section.

5. The miniature magnetic device as recited in claim 2, wherein said housing defines a major axis.

6. The miniature magnetic device as recited in claim 2, wherein said major axis of said housing is generally parallel to said major axis of said magnetic flux responsive element.

7. The miniature magnetic device as recited in claim 5, wherein said sensing plane of said magnetic responsive element is generally parallel to said major axis of said housing.

8. The miniature magnetic device as recited in claim 2, wherein said one or more flux concentrators are generally L-shaped.

9. The miniature magnetic device as recited in claim 8, wherein said one or more L-shaped flux concentrators define legs, disposed so that the legs extend below a bottom surface of said magnetic flux responsive element.

10. A miniature magnetic encoder comprising:
a magnetic flux responsive element having two or more extending leads, the magnetic flux responsive element formed in a generally rectangular shape defining a major axis and a pair of sides generally parallel to said major axis;
one or more flux concentrators disposed adjacent to said flux responsive element; and
a housing overmolded over said magnetic flux responsive element, defining a major axis, said one or more flux concentrators and a portion of said extending leads, said magnetic flux responsive element, one or more flux concentrators and said housing configured to have a footprint of around 5 mm.

11. The miniature magnetic encoder as recited in claim 10, wherein said magnetic flux responsive element is a Hall effect device defining a sensing plane parallel to said major axis of said Hall effect device; Hall effect device configured so that its sensing plane is generally parallel with the major axis of said housing.

12. The miniature magnetic encoder as recited in claims 11, wherein said one or more flux concentrators are formed with an L-shape configuration defining legs.

13. The miniature magnetic encoder as recited in claim 12, wherein said L-shaped flux concentrators are juxtaposed so that the legs extend below the bottom surface of said Hall effect device.

14. A method for making a miniature magnetic encoder comprising the steps of:
(a) providing a magnetic flux responsive element having two or more extending leads;
(b) providing one or more flux concentrators;
(c) juxtaposing said one or more flux concentrators adjacent to said magnetic flux responsive element;
(d) overmolding over said magnetic flux responsive element, said one or more flux concentrators and a portion of said extending leads.

15. The method as recited in claim 14, wherein step (d) comprises:
overmolding said magnetic flux responsive element and said one or more flux concentrators in a housing having a footprint of about 5 mm.

16. The method as recited in claim 14, wherein step (a) comprises:
providing a Hall effect device defining a major axis and opposing sides parallel to said major axis.

17. The method as recited in claim 16, wherein step (b) comprises:
providing one or more flux concentrators configured in a generally L-shape having extending legs.

18. The method as recited in claim 17, wherein step (c) comprises:
juxtaposing said one or more flux concentrators such that said extending legs extend to a point below the bottom surface of said Hall effect device.

19. The miniature magnetic device recited in claim 1, wherein said housing is formed from a magnetic resin, said housing defining a major axis.

20. The miniature magnetic device as recited in claim 19, wherein said major axis of said housing is generally parallel to said major axis of said magnetic flux responsive element.

21. The miniature magnetic device as recited in claim 19, wherein said magnetic flux responsive element is a Hall effect device.

22. The miniature magnetic device as recited in claim 19, further including one or more flux concentrators.

23. The miniature magnetic device as recited in claim 22, wherein said one or more flux concentrators are formed in said housing.

24. The miniature magnetic device as recited in claim 23, wherein said one or more flux concentrators are found by way of a protuberance.

25. The miniature magnetic device as recited in claim 24, wherein said one or more protuberances are generally parallel to the major axis of said housing.

26. The miniature magnetic device as recited in claim 25, wherein said protuberances are formed adjacent to an end of said housing opposite said extending leads.

27. The miniature magnetic device as recited in claim 19, wherein said housing is formed isotropically.

28. The miniature magnetic device as recited in claim 19, wherein said housing is formed anisotropically.

29. The miniature magnetic device recited in claim 1, further including:
a magnet having opposing North and South magnetic poles, said magnet juxtaposed adjacent to one of said space apart parallel sides of said magnetic flux responsive element; and
a flux concentrator disposed adjacent to the other of said two spaced apart sides of said magnetic flux responsive element.

30. The miniature sensor as recited in claim 29, wherein said housing is molded over said magnetic flux responsive element, said flux concentrator, said magnet and a portion of said extending leads.

31. The miniature sensor as recited in claim 30, wherein said housing is formed from a thermoplastic material.

32. The miniature sensor as recited in claim 30, wherein said housing is formed from a resin.

33. The miniature magnetic sensor as recited in claim 32, wherein said resin is epoxy.

34. The miniature magnetic sensor as recited in claim 29, wherein said magnetic flux responsive element is a Hall effect device wherein one of said spaced apart parallel sides defines a sensing plane.

35. The miniature magnetic sensor as recited in claim 34, wherein said flux concentrator is juxtaposed adjacent to said sensing plane.

36. The miniature magnetic sensor as recited in claim 29, wherein said flux concentrator is formed with a generally rectangular cross section.

37. The miniature magnetic sensor as recited in claim 35, wherein said magnet is juxtaposed adjacent to the other of said spaced apart parallel sides of said magnetic flux responsive element.

38. The miniature magnetic sensor as recited in claim 37, wherein said magnets is formed with at least one flat side.

39. The miniature magnetic sensor as recited in claim 38, wherein said magnet is formed with a magnetic pole adjacent to said flat side.

40. A miniature magnetic sensor comprising:
a generally rectangular Hall effect device which includes two parallel spaced apart sides defining a major axis generally parallel thereto, one of said two parallel spaced apart sides defining a sensing plane, said Hall effect device including two or more extending leads for connection to an external circuit;
a magnet having at least one flat side formed with a magnetic pole adjacent to said flat side, said magnet juxtaposed so that said at least one flat side is adjacent to one side of said Hall effect device opposite said sensing plane;
a flux concentrator having a least one flat side juxtaposed adjacent to said sensing plane of said Hall effect device; and
a housing for said magnetic flux responsive device, said magnet, said flux concentrator and a portion of said extending leads.

41. The miniature magnetic sensor as recited in claim 40, wherein said housing is formed by overmolding said magnetic flux responsive device, said magnet, said flux concentrator and a portion of said extending leads.

42. The miniature magnetic sensor as recited in claim 41, wherein said housing is formed from a thermoplastic material.

43. A process for forming a miniature magnetic sensor comprising the steps of:
(a) providing a Hall effect device formed with a generally rectangular shape defining two parallel space apart sides and a major axis generally parallel thereto, one of said sides defining a sensing plane, said Hall effect device formed with a pair of extending leads for connection to an external circuit;
(b) providing a magnet having at least one flat side, said magnet formed with one magnetic pole adjacent to said flat side;
(c) juxtaposing said magnet so that its flat side is adjacent to a side of the Hall effect device opposite said sensing plane;
(d) providing a flux concentrator having at least one flat side;
(e) juxtaposing said flat side of said flux concentrator adjacent to said sensing plane of said Hall effect device;
(f) forming a housing for carrying said Hall effect device, said flux concentrator said magnet and a portion of said extending leads.

44. The process as recited in claim 43, wherein said housing is formed by overmolding.

45. The process as recited in claim 43, wherein said housing is formed with a footprint of about 5 mm.

46. The process as recited in claim 43, wherein said housing is formed from a thermoplastic material.
